(19) United States
(12) Patent Application Publication
(10) Pub. No.: US 2007/0069367 A1
(43) Pub. Date: Mar. 29, 2007

(54) Reduced stress on SAW die with surrounding support structures

(75) Inventors: Scott L. Bunyer, Freeport, IL (US); Steven J. Magee, Lena, IL (US)

Correspondence Address: Bryan Anderson;Attorney, Intellectual Property, Honeywell International Inc., 101 Columbia Rd., P.O. Box 2245, Morristown, NJ, 07962, US

(73) Assignee: Honeywell International Inc.

(21) Appl. No.: 11/528,964

(22) Filed: Sep. 27, 2006

Related U.S. Application Data
(63) Continuation-in-part of application No. 11/238,483, filed on Sep. 28, 2005.

(51) Int. Cl. H01L 23/053

(52) U.S. Cl. 257/701; 257/782; 257/E23.005

(57) ABSTRACT

A die structural support apparatus and method are disclosed, in which a die component is provided. A support element can be configured for use with the die component, wherein said support element surrounds said die component, thereby strengthening said die component to provide a surrounding die support structure thereof. The die component preferably constitutes a SAW die, and may be formed from, for example, quartz. The support element can be molded, stamped, cast, machined and so forth and is preferably located with respect to the SAW die after the SAW die is formed.

### RELATED PATENT APPLICATIONS

This application is a Continuation-In-Part (CIP) under 25 U.S.C. § 120 of U.S. patent application Ser. No. 11/238,483 filed on Oct. 23, 2003, and incorporated herein by reference in its entirety.

### TECHNICAL FIELD

Embodiments are generally related to surface acoustic wave (SAW) devices and components. Embodiments are also related to SAW die and methods for manufacturing and producing SAW die. Embodiments are additionally related to SAW die structures.

### BACKGROUND OF THE INVENTION

Surface acoustic wave (SAW) devices are utilized in a number of industrial, commercial, consumer and military applications. SAW technology is generally characterized by its reliance on acoustic energy and electrical/acoustic transducers. SAW components are based on devices in which radio frequency signals are converted to acoustic signals and confined within a small substrate made from, for example, Lithium Niobate or other crystalline materials. SAW waves propagate at relatively low speed with reference to radio waves and, as such, a small substrate may produce relatively long time delays. SAW devices are useful, however, for example, devices such as filters utilized in wireless applications and sensors utilized in various environmental detection applications, such as pressure, torque and/or temperature sensors.

SAW devices are manufactured from a SAW die. Such components are typically manufactured with quartz, which is utilized because the quartz provides for minimal hysteresis, low creep, low aging and improved long-term stability. One of the problems with quartz is that it is very brittle and can fracture if the die is over-stressed. Currently the strength of the quartz can be increased by various methods. The methods used to increase the strength of the quartz can add considerable cost to the manufactured part.

It is therefore believed that an improved apparatus is required, which reduces the stress associated with a die component, such as a SAW die, while strengthening the die component itself, without cracking. Such an apparatus is disclosed herein in greater detail.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide for an improved structure for a die component.

It is another aspect of the present invention to provide for an apparatus that reduces the stress in a die component by incorporating a surrounding support structure.

The aforementioned aspects of the invention and other objectives and advantages can now be achieved as described herein. A die structural support apparatus and method are disclosed, in which a die component is provided. A support element can be configured for use with the die component, wherein said support element surrounds said die component, thereby strengthening said die component to provide a surrounding die support structure thereof. The die component preferably constitutes a SAW die, and may be formed from, for example, quartz. The support element can be molded, stamped, cast, machined and so forth and is preferably located with respect to the SAW die after the SAW die is formed.

The separate support element thus surrounds the SAW die to strengthen it. The support element can be ceramic, plastic, metal, quartz, etc. The support element or support piece can be pressed down about the SAW die or may be configured with a small gap for clearance. If a small clearance is utilized, the gap can create a wicking action for the adhesive, which in turn can be utilized to hold the SAW to a transducer package. The adhesive wicking up into this gap can also strengthen the quartz.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a top view of a die component;

FIG. 2 illustrates a top view of a die structural support apparatus, which can be implemented in accordance with a preferred embodiment;

FIG. 3 illustrates a top view of a die structural support apparatus, which can be implemented in accordance with an alternative embodiment;

FIG. 4 illustrates a side cut view of a die structural support apparatus, which can be implemented in accordance with a preferred embodiment; and

FIG. 5 illustrates a side cut view of a die structural support apparatus, which can be implemented in accordance with an alternative embodiment.

### DETAILED DESCRIPTION OF THE INVENTION

The particular values and configurations discussed in these non-limiting examples can be varied and are cited merely to illustrate at least one embodiment of the present invention and are not intended to limit the scope of the invention.

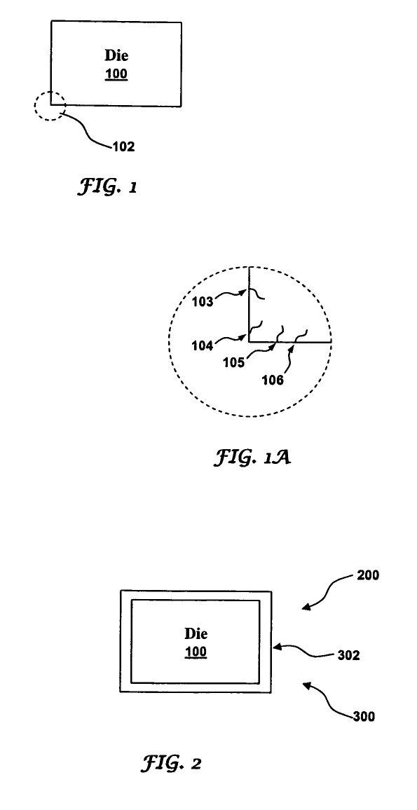

FIG. 1 illustrates a top view of a die component 100 (e.g. a SAW die). In the configuration depicted in FIG. 1, a detail is shown with respect to a section 102 of the die component 100. As indicated in FIG. 1, a plurality of micro cracks 104, 106, 108, and 110 may form in the die component 100.

FIG. 2 illustrates a top view of a die structural support apparatus 200, which can be implemented in accordance with a preferred embodiment. The die structural support apparatus 200 generally includes a die component 100 and a support element 302 that surrounds said die component 100, thereby strengthening said die component 100 to provide a surrounding die support structure thereof. The die component 100 can be, for example, a SAW die and may be preferably formed from quartz. The support element 302 functions as a separate piece that surrounds the die component 100 to strengthen it. The support element 302 can be configured from, for example, ceramic, plastic, metal, quartz and the like, depending upon design considerations. Support element 302 is preferably, however, configured form quartz.

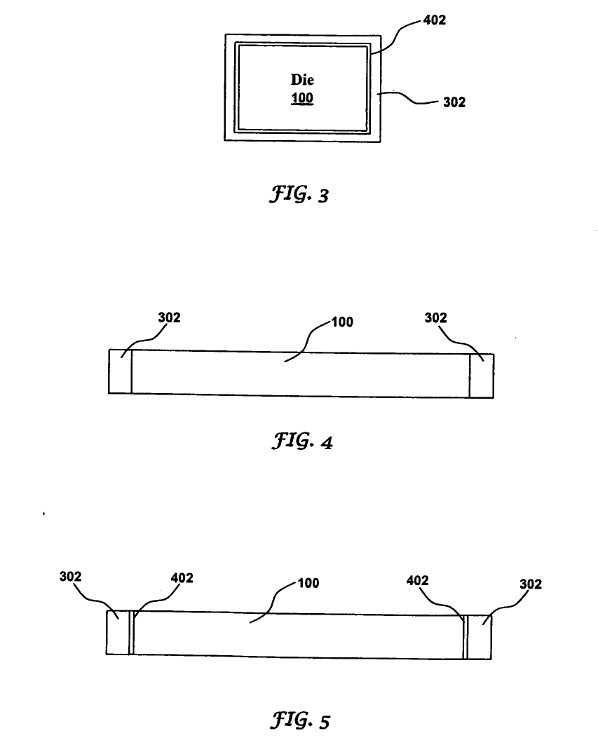

FIG. 3 illustrates a top view of a die structural support apparatus 300, which can be implemented in accordance with an alternative embodiment. Note that in FIGS. 2-3, identical or similar parts or elements are generally indicated by identical reference numerals. In general, the die component 100 is surrounded by the support element 302. The support element 302 can be pressed down about the die component 100 as indicated in FIG. 2, or can provide for a small gap 402 for clearance as depicted in FIG. 3. It the small clearance of gap 402 is implemented as indicated in FIG. 3, the gap 402 can create a wicking action for an adhesive for use in holding the die component 100 to a transducer package. The adhesive wicking up into gap 402 can also contribute to strengthening the die component 100. The support element 302 can be molded, stamped, cast, machine, and so forth, depending upon design considerations.

FIG. 4 illustrates a side cut view of a die structural support apparatus, which can be implemented in accordance with a preferred embodiment. FIG. 4 corresponds to FIG. 2 and shows the die 100 and the support element 302 from the side. A cut view is used so that the die 100 and the support element 302 can both be seen. Notice that the support element 302 does not lie underneath the die 100. As such, the entire die structural support apparatus can be inserted into a socket or chip carrier. The support element 302 is not a socket or a chip carrier in that it does not contain electrical contacts and does not lie over or under the die 100. The support element 302 surrounds the die 100 and can supply mechanical support and protection.

FIG. 5 illustrates a side cut view of a die structural support apparatus, which can be implemented in accordance with an alternative embodiment. FIG. 5 corresponds to FIG. 3 and shows the die 100, the support element 302, and the gap 402 from the side. A cut view is used so that the die 100, the gap 402, and the support element 302 can all be seen. Notice that the support element 302 does not lie underneath the die 100. As such, the entire die structural support apparatus can be inserted into a socket or chip carrier. The support element 302 is not a socket or a chip carrier in that it does not contain electrical contacts and does not lie over or under the die 100. The support element 302 surrounds the die 100 and can supply mechanical support and protection.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A die structural support apparatus, comprising:
a SAW die; and
a support element, wherein said support element surrounds said SAW die and wherein said support element does not underlie said SAW die, thereby strengthening said die component to provide a surrounding die support structure thereof.

2. The apparatus of claim 1 wherein said die component comprises a SAW die.

3. The apparatus of claim 1 wherein said die component comprises quartz.

4. The apparatus of claim 1 wherein said support element is molded.

5. The apparatus of claim 1 wherein said support element is stamped.

6. The apparatus of claim 1 wherein said support element is cast.

7. The apparatus of claim 1 wherein said support element is machined.

8. The apparatus of claim 1 wherein said support element surrounds said die component in order to form a gap between said die component and said support element.

9. The apparatus of claim 8 wherein said gap provides a clearance that results in a wicking action for an adhesive that is utilized to hold said die component to a transducer package thereof.

10. The apparatus of claim 1 wherein said support element comprises ceramic.

11. The apparatus of claim 1 wherein said support element comprises plastic.

12. The apparatus of claim 1 wherein said support element comprises metal.

13. The apparatus of claim 1 wherein said support element comprises quartz.

14. A die structural support apparatus, comprising:
a SAW die;
a support element, wherein said support element surrounds said SAW die and wherein a gap between said SAW die and said support element provides for a wicking action; and
an adhesive filling the gap wherein said adhesive can be created by the wicking action, thereby strengthening said die component to provide a surrounding die support structure thereof.

15. The apparatus of claim 1 wherein said support element comprises at least one of the following types of materials: ceramic, plastic, metal or quartz.

16. A method for forming a die structural support apparatus, comprising:
forming a SAW die; and
surrounding said SAW die with a support element, wherein said support element surrounds said SAW die and wherein said support element does not overlie or underlie said SAW die, to thereby strengthen said SAW die and provide a surrounding die support structure thereof.

17. The method of claim 16 further comprising configuring said support element from at least one of the following types of materials: ceramic, plastic, metal or quartz.

18. The method of claim 16 further comprising forming said support element by at least one of the following types of process steps:
molding said support element;
stamping said support element;
casting said support element; or
machining said support element.

19. The method of claim 16 wherein said support element surrounds said die component in order to form a gap between said die component and said support element.

20. The method of claim 19 wherein said gap provides a clearance that results in a wicking action for an adhesive that is utilized to hold said die component to a transducer package thereof.
